(19) United States
(12) Patent Application Publication
(10) Pub. No.: US 2022/0102580 A1
(43) Pub. Date: Mar. 31, 2022

(54) WAFER BONDING FOR EMBEDDING ACTIVE REGIONS WITH RELAXED NANOFEATURES

(71) Applicant: The Regents of the University of California, Oakland, CA (US)

(72) Inventors: Caroline E. Reilly, Goleta, CA (US); Umesh K. Mishra, Montecito, CA (US); Stacia Keller, Santa Barbara, CA (US); Steven P. DenBaars, Goleta, CA (US)

(73) Assignee: The Regents of the University of California, Oakland, CA (US)

(21) Appl. No.: 17/422,867

(22) PCT Filed: Jan. 16, 2020
(86) PCT No.: PCT/US20/13896

§ 371 Date: Jul. 14, 2021

Related U.S. Application Data
(60) Provisional application No. 62/793,236, filed on Jan. 16, 2019.
(60) Provisional application No. 62/793,503, filed on Jan. 17, 2019.

(51) Int. Cl. H01L 33/00; H01L 31/18; H01L 33/02

(52) U.S. Cl. CPC H01L 33/0093; H01L 33/025; H01L 31/1892; H01L 31/1848

(57) ABSTRACT

A method for fabricating a device, as well as the device itself, which includes growing a bonding layer on a first wafer or substrate, wherein the bonding layer includes at least partially relaxed features; and then bonding a second wafer or substrate to the features in on the first wafer or substrate, to cap and contact the features with separately grown material.

### CROSS REFERENCE TO RELATED APPLICATIONS

This application claims the benefit under 35 U.S.C. Section 119(e) of the following co-pending and commonly-assigned applications:

U.S. Provisional Patent Application No. 62/793,236, filed Jan. 16, 2019, by Caroline Reilly, Umesh K. Mishra, Stacia Keller, and Steven P. DenBaars, entitled “WAFER BONDING FOR EMBEDDING ACTIVE REGIONS WITH RELAXED NANOFEATURES” Attorney's Docket No. 30794.712-US-P1 (2019-395);

U.S. Provisional Patent Application No. 62/793,503, filed Jan. 17, 2019, by Caroline Reilly, Umesh K. Mishra, Stacia Keller, and Steven P. DenBaars, entitled “WAFER BONDING FOR EMBEDDING ACTIVE REGIONS WITH RELAXED NANOFEATURES” Attorney's Docket No. 30794.712-US-P2 (2019-395);

all of which applications are incorporated by reference herein.

### STATEMENT REGARDING FEDERALLY SPONSORED RESEARCH AND DEVELOPMENT

This invention was made with Government support under Cooperative Agreement No. DE-AR0000671 from the Department of Energy. The Government has certain rights in this invention.

### BACKGROUND OF THE INVENTION

### 1. Field of the Invention

This invention relates to wafer bonding for embedding active regions with relaxed nanofeatures.

### 2. Description of the Related Art

(Note: This application references a number of different publications as indicated throughout the specification by one or more reference numbers within brackets, e.g., [x]. A list of these different publications ordered according to these reference numbers can be found below in the section entitled “References.” Each of these publications is incorporated by reference herein.)

Semiconductor device systems rely on utilizing materials of high crystal quality with minimal defects to perform their functions optimally. Devices of these types include but are not limited to transistors, light-emitting diodes (LEDs), and laser diodes (LDs), comprised of Si, Ge, or III-V materials, with Group III materials being combinations of gallium, aluminum, and indium used in phosphides, arsenides, and nitrides or appropriate alloys thereof. Epitaxial growth techniques, such as metal organic chemical vapor deposition (MOCVD) and molecular beam epitaxy (MBE), are used to grow high crystal quality materials for devices.

Different materials with varying lattice structures and lattice constants, as well as materials with the same lattice structures, may be grown epitaxially with differing amounts of strain in the material due to lattice constant mismatch. Lattice constant mismatch between materials may cause thick epitaxial growth to produce poor quality material with high numbers of defects due to relaxation of the material occurring past a critical growth thickness. These defects can degrade device performance significantly.

For thin epitaxial growth, such as layers used in active regions of devices, defect-free coherently strained layers can be grown despite some degree of lattice mismatch, typically up to a lattice mismatch of 3%. The material on either side of the active region typically has the same lattice constant, therefore the active region must stay strained for the thick material grown on top of the active region to be unstrained and defect free.

However, a larger lattice mismatch, such as that between GaN and InN, causes even very thin layers required for active regions to be relaxed on the underlying material, forming quantum dot (QD) nanostructures. This significant lattice mismatch is necessary for longer wavelength LEDs and LDs in the nitride system where InGaN with high percentages of indium must be obtained in the active region.

Nanostructured relaxed material can also be achieved utilizing fabrication techniques to relax the material. Nanostructured active regions have been shown to provide other benefits to the active regions of devices due to confinement of carriers.

Having a relaxed active region, however, prevents growth of thick defect-free material on top of the active region. The degradation in crystal quality of the material will decrease device performance.

What is needed, then, is a relaxed active region without degraded crystal quality. The present invention satisfies these needs.

### SUMMARY OF THE INVENTION

The present invention discloses a method for fabricating a device, as well as the device itself, wherein the method comprises growing at least partially relaxed features (e.g., structures) on a first wafer or substrate; and then bonding a second wafer or substrate to the at least partially relaxed features on the first wafer or substrate, e.g., to cap and contact the relaxed nanostructures or microstructures with separately grown material. In one or more examples, a device layer grown on the first substrate, wherein the device layer includes the at least partially relaxed features.

The method and device can be embodied in many ways including, but not limited to, the following.

1. A method of making a device, comprising:

(a) forming one or more at least partially relaxed features comprising one or more planar layers, one or more nanostructures, and/or one or more microstructures, on a first substrate; and

(b) bonding a second substrate to the at least partially relaxed features on the first substrate.

2. The method of example 1, wherein the at least partially relaxed features are rigid or hard.

3. The method of example 2, wherein at least some of the at least partially relaxed features crack under stress, but serve to preserve others of the features from cracking.

4. The method of example 1, wherein the features are plastic or soft.

5. The method of example 4, wherein the features deform under stress to increase a bonding area.

6. The method of example 1, wherein the features comprise InGaN quantum dots (QDs).

7. The method of example 6, wherein the InGaN quantum dots are grown on n-GaN on the first substrate and are bonded to p-GaN on the second substrate.

8. The method of example 1, wherein the features comprise a significant lattice mismatch with the second substrate, the significant mismatch corresponding to the lattice mismatch arising from the features having a different crystal orientation or different material than the second part.

9. The method of example 1, wherein the features are not planar.

10. The method of any of the preceding examples 1-9, comprising repeating the steps (a) and (b) so as to form a device comprising a plurality of pairs comprising the first substrate bonded to the second substrate, wherein the second substrate in a first one of the pairs is the first substrate in the next pair formed on top of the first one of the pairs.

11. The method of any of the preceding examples 1-10, wherein at least one of the first substrate or the second substrate are undergoing, or in a stage of, processing.

12. The method of any of the preceding examples 1-11, further comprising the layer comprising an active region including the features.

13. A device, comprising:

at least partially relaxed features formed on a first substrate; and a second substrate bonded to the at least partially relaxed features.

14. The device of example 13, wherein the at least partially relaxed features are rigid or hard.

15. The device of example 14, wherein some of the at least partially relaxed features crack under stress, but serve to preserve others of the at least partially relaxed features from cracking.

16. The device of example 15, wherein the at least partially relaxed features are plastic or soft.

17. The device of example 16, wherein the at least partially relaxed features deform under stress to increase a bonding area.

18. The device of any of the examples 13-17, further comprising a layer grown on the first substrate, wherein the layer comprises an active region including the at least partially relaxed features, the at least partially relaxed features comprising quantum dots.

19. The device of example 18, wherein the quantum dots (QDs) comprise InGaN QDs and the first substrate and the second substrate comprise gallium nitride.

20. The device of any of the examples 13-19, wherein the at least partially relaxed features are not planar or a first surface of the first substrate in contact with the at least partially relaxed features is not parallel to a second surface of the second substrate in contact with the features.

21. The device of any of the examples 13-20, wherein the device comprises a light emitting device, a light absorbing device, or an electronic device.

22. The device of any of the examples 13-21 comprising a p-n junction, wherein:

the first substrate comprises an n-type region,

the second substrate comprises a p-type region, and

a layer comprising the at least partially relaxed features comprises an intrinsic region, so as to form a p-type region-intrinsic region-n-type region (p-i-n) junction.

23. The device of any of the examples 13-22, wherein the at least partially relaxed features have a height and width in a range of 1-1000 nanometers or in a range of 1 micron to 1000 micrometers.

24. The device of any of the examples 13-23, wherein the at least partially relaxed features, the first substrate, and the second substrate comprise a semiconductor.

25. The device of example 24, wherein the semiconductor comprises a III-Nitride material or a III-V material.

26. The device of any of the examples 13-25, wherein the layer including the at least partially relaxed features comprises a wafer bond between the at least partially relaxed features and the second substrate, or the layer comprises a bond comprising the at least partially relaxed features formed by wafer bonding the first substrate to the second substrate.

27. The device of any of the examples 13-26, wherein one or more in-plane lattice constants of the at least partially relaxed features assume their natural value in the absence of strain.

28. The device of any of the examples 13-27, wherein the at least partially relaxed features have a relaxation between 1%-99% or are fully (100%) relaxed.

29. The device of any of the examples 13-28, wherein additional ones of the at least partially relaxed features are formed on the second substrate, and the additional ones of the at least partially relaxed features are bonded to the at least partially relaxed features on the first substrate.

30. The device of any of the examples 13-29, wherein the at least partially relaxed features are etched features in the first substrate or the at least partially relaxed features are grown on the first substrate.

31. The device of any of the examples 13-30, further comprising comprises air gaps so that the device comprises the air gaps between the first substrate and the second substrate.

32. The device of any of the examples 13-31, wherein the at least partially relaxed features are grown through selective area epitaxy (SAE) or self-assembled growth.

33. The device of any of the examples 13-32, comprising a device layer grown on the first substrate, wherein the device layer includes the at least partially relaxed features.

### BRIEF DESCRIPTION OF THE DRAWINGS

Referring now to the drawings in which like reference numbers represent corresponding parts throughout:

FIGS. 1(a), 1(b), 1(c), 1(d), 1(e), 1(f), 1(g) and 1(h) illustrate steps of a method for bonding two wafers or substrates containing a top half and a bottom half of a device at an active region by utilizing the nanostructure of the active region to promote bonding.

FIGS. 2(a) and 2(b) are atomic force microscopy (AFM) images of InN QDs grown on a Ga-polar GaN template by MOCVD. Template and dots are grown by MOCVD.

FIGS. 3(a)-3(b) are X-ray refraction diffraction (XRD) reciprocal space maps (RMSs) around a GaN (11-24) reflection, wherein FIG. 3(a) shows a 20 nm thick continuous InN layer and FIG. 3(b) shows a nominally 1 nm thick InN layer comprising relaxed InN QDs grown on N-polar GaN.

FIG. 4 is flowchart illustrating a method of making a device.

FIG. 5 is a schematic cross-section of a device according to one or more embodiments described herein.

FIG. 6 is a cross section of an example device comprising a light emitting device, a light absorbing device, or an electronic device.

FIG. 7 is a cross-sectional schematic of an example of an at least partially relaxed feature.

### DETAILED DESCRIPTION OF THE INVENTION

In the following description of the preferred embodiment, reference is made to the accompanying drawings which form a part hereof, and in which is shown by way of illustration a specific embodiment in which the invention may be practiced. It is to be understood that other embodiments may be utilized and structural changes may be made without departing from the scope of the present invention.

### Technical Description

The present invention allows for relaxed nanostructured/microstructured layers (e.g., active regions) to be utilized in device structures. Relaxed nanostructures or microstructures can be produced for use in active regions when the active region material has a significant lattice mismatch with the substrate material. Other approaches to using relaxed active regions involve material growth on top of the relaxed material, which can degrade the crystal quality of the other device components, decreasing device performance.

Rather than growing over the relaxed nanostructures or microstructures, this invention applies the technique of wafer bonding to cap and contact the relaxed nanostructures in the active region with separately grown material. The nanostructures/microstructures of the active region serve as the contact points for the two wafers being bonded and may not need to be planar as is typical in wafer bonding techniques.

Improving material quality leads to enhanced device performance, with this invention providing a means to achieving high material quality devices, but also utilizing relaxed active region structures. Relaxed active regions can be beneficial in a variety of devices, including, but not limited to, long wavelength LEDs that suffer from a high lattice mismatch of the active region of the device and the surrounding device structure. The technique of wafer bonding is already commercially viable, and therefore the implementation of this invention would fit into the current infrastructure.

Applications of this invention include, but are not limited to, III-V materials for LEDs and LDs for long wavelength emissions in which the active region has a large lattice mismatch with the surrounding device structure.

### EXAMPLES

The present invention allows for relaxed nanostructured or microstructured active regions to be utilized in device structures without decreasing the material quality of other device components due to the lattice mismatch in the active region. This invention makes it feasible to utilize a relaxed nanostructured/microstructured active region without degrading the crystal quality of the rest of the device. Rather than growing over the relaxed nanostructures, this invention applies the technique of wafer bonding to cap and contact the relaxed nanostructures in the active region with separately grown material.

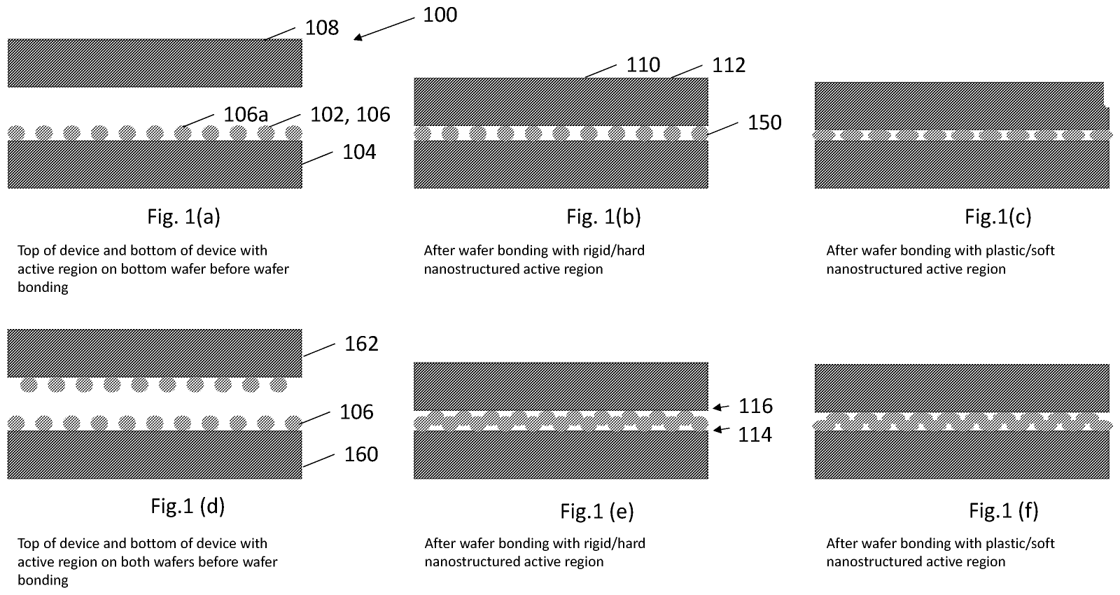

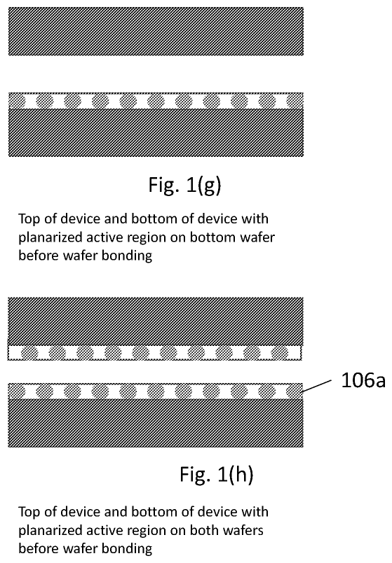

In this method, two wafers or substrates containing a top half and bottom half of a device are bonded at an active region by utilizing the nanostructure of the active region to promote bonding, which is shown in FIGS. 1(a)-1(f).

Specifically, FIG. 1(a) illustrates the top of the device 100 and the bottom of the device 100 with the active region 102 on the bottom wafer 104 before wafer bonding; FIG. 1(b) shows the device after wafer bonding with a rigid/hard nanostructured active region 102 comprising nanostructures 106 or at least partially relaxed features 106a; FIG. 1(c) shows the device after wafer bonding with a plastic/soft nanostructured active region; FIG. 1(d) shows the top of the device and the bottom of the device with the active region on both wafers 104, 108 before wafer bonding; FIG. 1(e) shows the device after wafer bonding with the rigid/hard nanostructured active region; FIG. 1(f) shows the device after wafer bonding with the plastic/soft nanostructured active region; FIG. 1(g) shows the top of the device and the bottom of the device with a planarized active region on the bottom wafer before wafer bonding; and FIG. 1(h) shows the top of the device and the bottom of the device with a planarized active region on both wafers before wafer bonding.

The example used is a GaN/InGaN QD LED, but this invention can be applied to any device structure in the III-V system or other crystalline material systems in which relaxed active regions can be grown. A Ga-polar LED may be grown such that n-GaN is grown on an appropriate substrate, followed by an active region of a relaxed InGaN QD layer.

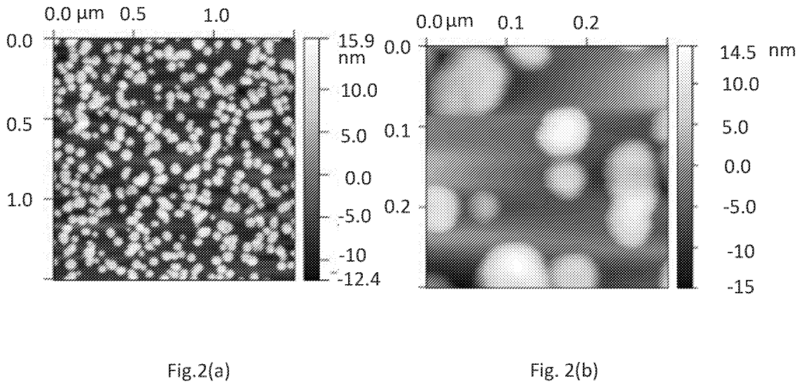

A layer of InN QDs grown under similar conditions is shown in FIGS. 2(a) and 2(b). On a separate substrate, N-polar p-GaN may be grown. The wafers may be treated or processed as desired after growth. By contacting the growth surfaces of the two wafers and applying pressure, wafer bonding may be completed.

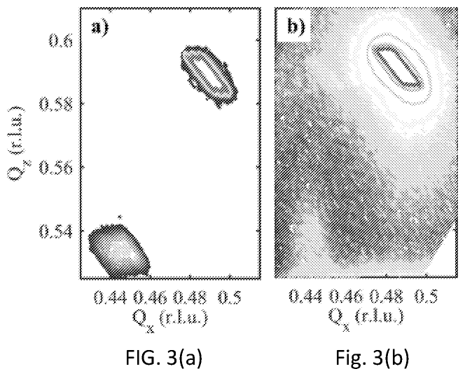

The active region may not need to be perfectly planar as the nanostructured active region serves as posts for contact points at the top of the dots. As seen in FIG. 1(d), both wafers may have an active region or nanostructured region to promote bonding. For instance, FIGS. 3(a) and 3(b) shows relaxed InN QDs grown on N-polar GaN. [1]

Depending on the material, the nanostructures may stay rigid throughout the bonding process or may deform under stress and increase the bonded area, as shown in FIGS. 1(b), 1(c), 1(e), and 1(f). If the material is rigid and prone to cracking, some of the nanostructures that are slightly taller may crack but serve to preserve the remaining dots from cracking.

Depending on the density of the nanostructures and the nature of the materials involved, the strength of the wafer bonding may vary.

### Process Steps

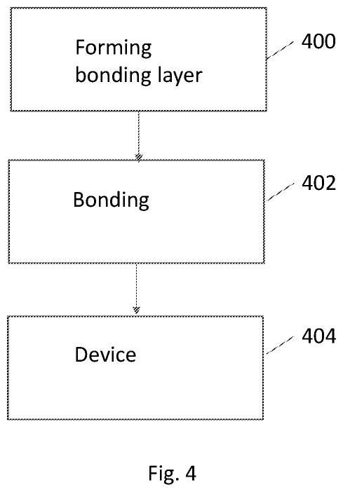

FIG. 4 is a flowchart illustrating a method of making a device. The method comprises the following steps (referring also to FIGS. 1(a)-1(h), FIG. 5, and FIG. 6).

Block 400 represents forming a layer 150 (e.g., device layer) on a first part 160. Examples of the first part include, but are not limited to, one or more first materials, a first set of device layers, a first wafer, or a first substrate (e.g., comprising a wafer). The layer 150 includes at least partially relaxed features 106a (e.g., structures) comprising one or more planar layers, one or more nanostructures, or one or more microstructures. The layer or at least partially relaxed features may be grown or etched onto the first part 160 (e.g., first substrate).

Block 402 represents bonding a second part 162 to the at least partially relaxed features on the first wafer or substrate (for example, to cap and contact the at least partially relaxed features with separately grown material 110). Examples of the second part include, but are not limited to, one or more first materials, a second set of device layers, a second wafer, or a second substrate (e.g., comprising a wafer). In one or more examples, the separately grown material is included in the second part (e.g., wafer or substrate) or grown on the surface 112 of the second part (e.g., second wafer or substrate) opposite the surface contacting the features 106. In one or more examples, the separately grown material 110 is grown or formed on the second part prior to the bonding. In one or more examples, separately grown material comprises device layers such as a p-type region.

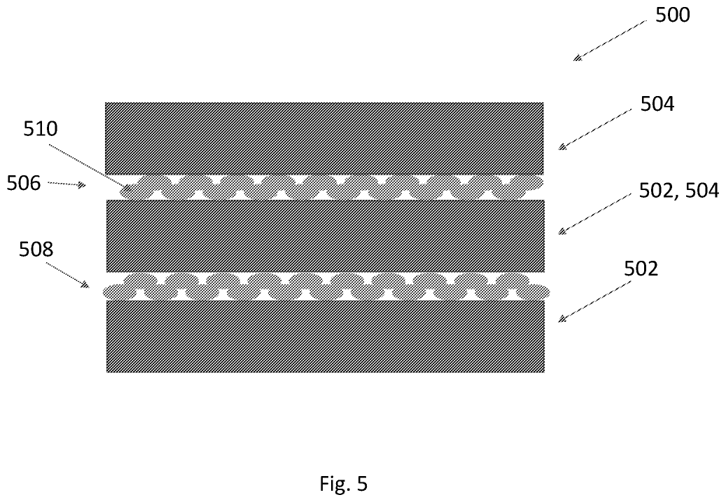

FIG. 5 illustrates an example wherein the steps 400 and 402 are repeated so as to form a device 500 comprising a plurality of pairs comprising the first part 502 bonded to the second part 504, wherein the second part in a first one of the pairs is the first part in the next pair or next part formed on top of the first one of the pairs. The different pairs may be connected via tunnel junctions 506. In one or more examples, a layer 508 (including the at least partially relaxed features 510 between the first part 502 and the second part 504) comprises or forms the tunnel junction 506 including an n-type layer forming a tunnel junction with a p-type layer. In one or more examples, the layer 508 comprises an n-type layer or p-type layer forming a tunnel junction with the p-type layer or n-type layer, respectively, in the first part 502 or the second part 504.

In one or more examples, at least one of the first part (e.g., first wafer or substrate) or the second part (e.g., second wafer or substrate) are undergoing, or in a stage of, processing (e.g., etching, contact deposition).

Block 404 represents the end result, a device. The device can be embodied in many ways including, but not limited to, the following.

1. A device 100, comprising:

at least partially relaxed features 106 formed in or on a first part (e.g., first substrate); and

a second part (e.g. second substrate 108) bonded to the at least partially relaxed features (for example, to cap and contact the features with separately grown material 110). In one or more examples, a layer 150 (e.g., bonding layer and/or an active region 102 or part of a device structure) grown on the first part (e.g., first substrate) and the layer includes the at least partially relaxed features.

2. The device of example 1, wherein the at least partially relaxed features are rigid or hard. In one or more examples, the at least partially relaxed features are rigid or hard so that the at least partially relaxed features do not deform or change shape (e.g., by more than 1-10%) as compared to before the bonding.

3. The device of example 1, wherein some of the at least partially relaxed features crack under stress (for example, to serve to preserve others of the features in the active region from cracking). In one or more examples, those at least partially relaxed features that crack under stress do so under the forces, pressures, and temperatures used during the bonding process (e.g., wafer bonding process) of bonding the second part to the first part.

4. The device of example 1, wherein the at least partially relaxed features are plastic or soft. In one or more examples, the at least partially relaxed features are plastic or soft so that the at least partially relaxed features deform or change shape (e.g., by more than 1-10%) as compared to before the bonding. In one or more examples, the features are plastic or soft so that the at least partially relaxed features deform or change shape or flatten under the forces and pressures applied during the bonding process.

5. The device of any of the examples 1-4, wherein the bonding causes the at least partially relaxed features to squeeze or compress against one another, or wherein the bonding causes some of the features between adjacent nanostructures to shift upwards.

6. The device of example 4, wherein the at least partially relaxed features deform under stress to increase a bonding area.

7. The device of any of the preceding examples, wherein the at least partially relaxed features comprise quantum dots.

8. The device of example 7, wherein the quantum dots (QDs) comprise InGaN QDs.

9. The device of example 7 or 8, wherein the quantum dots are grown on n-GaN on the first part and are bonded to p-GaN on the second part.

10. The device of any of the examples 1-9, wherein the at least partially relaxed features have a significant lattice mismatch with the second part (e.g., second substrate). In one or more examples, the significant mismatch corresponds to the lattice mismatch arising from the at least partially relaxed features having a different crystal orientation or different material than the second material (e.g., second wafer or substrate). In one or more examples, the features comprise a III-Nitride material and the second part (e.g., second substrate) comprises a different material or a III-V material different from III-Nitride. In one or more examples, the features comprise InN or InGaN having an indium composition in a range of 1-100% (e.g., pure InN) and the first substrate comprises gallium nitride. In another example, the features comprises InN or InGaN or InAs and the first substrate comprises GaN. In one or more further examples, one of the substrates 104, 108 comprises silicon or gallium arsenide and the other of the substrates comprises III-Nitride, e.g., first substrate 104 comprising III-Nitride, second substrate 108 comprising silicon or gallium arsenide.

11. The device of any of the examples 1-10, wherein the at least partially relaxed features are not planar or a first surface 114 of the first part in contact with the at least partially relaxed features is not parallel to a second surface 116 of the second part in contact with the at least partially relaxed features.

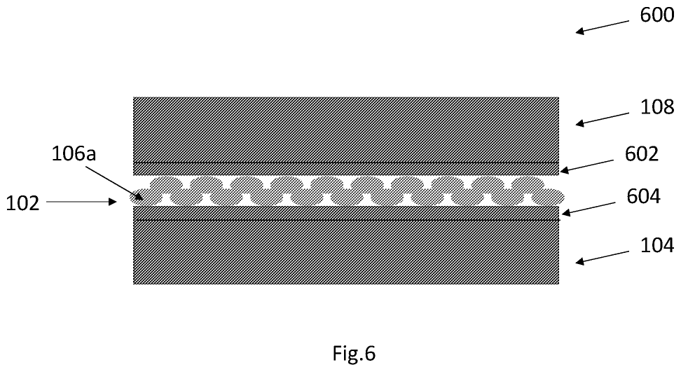

12. FIG. 6 illustrates the device 600 of any of the examples 1-11, wherein:

the second substrate 108 comprises a p-type material 602 (e.g., a p-type gallium nitride layer),

the first substrate 104 comprises an n-type material 604 (e.g., an n-type gallium nitride layer), and

electrons are injected into/received from the active region through the n-type material and holes are injected into/received from the layer 150 comprising an active region (including the at least partially relaxed features) through the p-type material when an electric field is applied across the n-type material and the p-type material.

13. The device of any of the examples 1-12 comprising a light emitting device (e.g., light emitting diode (LED) or laser diode or microLED), wherein the layer 150 comprising the active region (including the at least partially relaxed features) emits light or electromagnetic radiation in response to the electrons and holes recombining in the active region. In one or more examples, the device is a micro LED having a surface area of 1000×1000 microns or less. A plurality of microLEDs may be fabricated to form an array of the microLEDs.

14. The device 600 of any of the examples 1-12 comprising a light absorbing device (e.g., solar cell or photodetector), wherein:

the second substrate comprises a p-type material 602,

the first substrate comprises an n-type material 604,

electrons and holes are generated in the layer comprising an active region including the at least partially relaxed features) in response to electromagnetic radiation incident on the active region, and

the electrons are transferred from the active region into n-type material and holes are transferred from the active region into the p-type region when an electric field is applied across the n-type material and the p-type material.

15. The device 600 of any of the examples 1-14 comprising a p-n junction, wherein:

the first substrate comprises an n-type region 604,

the second wafer or substrate comprises a p-type region 602, and

the layer comprising an active region including the at least partially relaxed features comprises an intrinsic region, so as to form a p-type region-intrinsic region-n-type region (p-i-n) junction.

16. The device of any of the examples 1-14, wherein the layer comprises or forms a tunnel junction including an n-type layer forming a tunnel junction with a p-type layer. In one or more examples, the layer comprises an n-type layer or p-type layer forming a tunnel junction with the p-type layer or n-type layer, respectively, in the first substrate or second substrate.

17. The device of any of the examples 1-16 comprising a field effect transistor, wherein the first substrate comprises a source electrode, the layer 150 including the at least partially relaxed features comprises an active region comprises a channel region, the second substrate comprises a drain electrode, and the first substrate, or the second substrate, comprises a gate electrode controlling flow of current through the channel region between the source electrode and the drain electrode.

18. The device of any of the examples 1-11 comprising a field effect transistor, wherein:

the first wafer or substrate comprises a source electrode, a drain electrode, and a gate electrode,

the layer 150 comprising the at least partially relaxed features comprising an active region comprises a channel region, and

the gate electrode controls flow of current through the channel region between the source electrode and the drain electrode.

18. The device of any of the examples 1-11 comprising an electronic device 600 (e.g., a transistor such as, but not limited to, a field effect transistor).

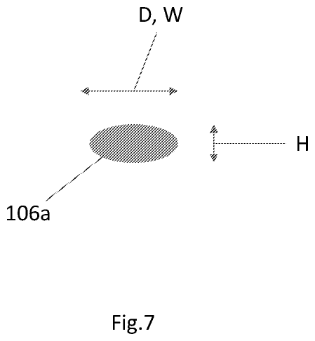

19. The device of any of the examples 1-11, wherein the at least partially relaxed features have a height H and width W (or diameter D) in a range of 1-1000 nanometers or 1-1000 micrometers (see FIG. 7). In one or more examples, the height, the width, and the diameter are the maximum (largest) height, maximum (largest) width and maximum (largest) diameter.

20. The device of any of the examples 1-19, wherein the at least partially relaxed features, the first part, and the second part comprise a semiconductor.

21. The device of any of any of the examples 1-20, wherein the at least partially relaxed features comprise a III-Nitride material or a III-V material comprising at least one element from Group III of the periodic table and at least one element from Group V of the periodic table.

22. The device of any of the examples 1-21, further comprising the layer 150 comprising a bonding layer including a wafer bond between the at least partially relaxed features and the second part, or a bond comprising the at least partially relaxed features formed by wafer bonding the first part to the second part. In one or more examples, bonding conditions (e.g., pressure and temperature) are sufficient to cause bonding of the second part to the at least partially relaxed features and the first part. Examples of bonding include, but are not limited to, thermocompression bonding, wafer bonding, or any other suitable wafer bonding technique.

23. The device of any of the examples 1-22, wherein the at least partially relaxed features have a spherical shape or elliptical cross section, an obloid, ellipsoid, a spheroid, or a prolate spheroid, or a hexagonal or triangular cross section.

24. The device of any of the examples 1-23, wherein the first part, the second part, and/or the layer 150 including the features have a semipolar, polar, or non polar orientation.

25. The device of any of the examples 1-24, wherein the first part and/or the second part comprise a semiconductor (e.g., III-Nitride) grown on a foreign substrate (e.g., sapphire).

26. The device of any of the examples 1-25, wherein in-plane lattice constants of the at least partially relaxed features are at least partially relaxed (1%-99%) or the in-plane lattice constant of the nanostructures assume their natural value in the absence of strain (e.g., 100% relaxed). In one or more examples, at least partially relaxed features comprise the in-plane lattice constants (between neighboring atoms in a plane of the crystal) that are changed by 1% to 99% or 1%-400% of their natural relaxed (unstrained) value.

In one or more examples herein, for a layer X (e.g., active region or nanostructures) grown on a layer Y (e.g., first wafer or substrate), for the case of coherent growth, the in-plane lattice constant(s) of X are constrained to be the same as the underlying layer Y. If X is fully relaxed, then the lattice constants of X assume their natural (i.e. in the absence of any strain) value. If X is neither coherent nor fully relaxed with respect to Y, then it is considered to be partially relaxed. In some cases, the substrate might have some residual strain.

27. The device of any of the examples 1-26, wherein additional ones of the at least partially relaxed features are formed (e.g., by etching or growth) on the second substrate, and the additional ones of the at least partially relaxed features comprise nanostructures, microstructures, or planar layers bonded to the at least partially relaxed features on the first substrate.

28. The device of any of the examples 1-27, wherein the at least partially relaxed features are etched features in the first substrate and/or second substrate or the at least partially relaxed features are grown on the first substrate and/or second substrate.

29. The device of any of the examples 1-28, wherein the layer 150 including the at least partially relaxed features comprises air gaps so that the device comprises the air gaps between the first substrate and the second substrate.

30. The device of any of the examples 1-29, wherein the at least partially relaxed features are grown through selective area epitaxy (SAE), lateral epitaxial overgrowth, or self-assembled growth.

31. The present disclosure further describes a method of making a device according to any of the examples 1-30. The method may comprise (a) forming one or more at least partially relaxed features comprising one or more planar layers, one or more nanostructures, and/or one or more microstructures, on a first substrate; and (b) bonding a second substrate to the at least partially relaxed features on the first substrate.

32. The device or method of any of the claims 1-31, further comprising a device layer grown on the first substrate, the device layer including the at least partially relaxed features and the device layer comprising an active region, a contact layer, or a tunnel junction.

33. The device of method of any of the claims 1-32, further comprising an electrical contact (e.g., ohmic contact, metal contact, and/or contact pad) to the n-type region and a contact to the p-type region (e.g., ohmic contact, metal contact, and/or contact pad). In one or more examples, the electrical contact to the n-type region is on the first substrate and the electrical contact to the p-type region is on the second substrate. In one or more examples, the layer comprising the at least partially relaxed features includes an electrical contact to the device. In one or more examples, the first substrate 104 and the second substrate 108 comprise further device layers (e.g., n-type region 604 and p-type region 602) as needed for the functioning of the device.

### Benefits and Advantages

The present invention provides a number of benefits and advantages:

(a) This technique can be applied to nanostructured active regions, as described, as well as microstructured or planar active regions to allow for relaxed layers in devices.

(b) Bonding parts of the device other than the active region for various device structures can also be conducted, such as bonding for contact layers.

(c) The nanostructures/microstructures/planar layers may exist on either or both wafers.

(d) A variety of device geometries may be imagined other than the two-wafer process as described, including but not limited to devices with larger etched features.

(e) The method may also be applied to non-relaxed or partially relaxed nanostructures or microstructures in the active region or as another layer of the device.

(f) The method can be applied multiple times within the same device structure, such that wafer bonding occurs multiple times to create device layers.

(g) The material used may be grown through a variety of epitaxial techniques including but not limited to metal organic chemical vapor deposition (MOCVD) and molecular beam epitaxy (MBE).

(h) The material may be grown with a variety of precursors using the different techniques.

(i) Many layers may exist in either of both of the wafers, consistent with the desired device structure.

(j) Any appropriate substrate may be used to grow these materials for bonding.

(k) Different material systems that could otherwise not constitute one device can be bonded together, for instance bonding InAs quantum dots on GaAs to p-GaN.

(l) The wafer bonding method may apply to wafers at various stages of processing.

(m) This method is not limited to a specific crystal orientation and may serve to allow for multiple crystal orientations either separately or collectively.

(n) Filling of the gap/voids between the two wafers may be completed through planarization prior to bonding or through some other post bonding technique.

(o) An air gap may exist between the bonded wafers that may be desirable in some device geometries.

(p) The nanostructures, microstructures, or planar layer may be grown or fabricated in a variety of ways including but not limited to etching, selective area epitaxy (SAE), or self-assembled growth of nanostructures or microstructures.

(q) The devices that can be constructed via this method include but are not limited to LEDs, microLEDs, laser diodes (LDs), photodetectors, solar cells, transistors (FETs), and vertical-cavity surface emitting lasers (VCSELs).

### Nomenclature

GaN and its ternary and quaternary compounds incorporating aluminum and indium (AlGaN, InGaN, AlInGaN) are commonly referred to using the terms (Al,Ga,In)N, III-nitride, III-N, Group III-nitride, nitride, Al_{(1-x-y)}In_{y}GaₓN where 0<x<1 and 0<y<1, or AlInGaN, as used herein. In additions alloys with other metals such as Sc, for example, can be used. All these terms are intended to be equivalent and broadly construed to include respective nitrides of the single species, Al, Ga, and In, as well as binary, ternary and quaternary compositions of such Group III metal species. Accordingly, these terms comprehend the compounds AlN, GaN, and InN, as well as the ternary compounds AlGaN, GaInN, AlInN, and ScAlN and the quaternary compound AlGaInN, as species included in such nomenclature. When two or more of the (Ga, Al, In) component species are present, all possible compositions, including stoichiometric proportions as well as “off-stoichiometric” proportions (with respect to the relative mole fractions present of each of the (Ga, Al, In) component species that are present in the composition), can be employed within the broad scope of the invention. Accordingly, it will be appreciated that the discussion of the invention hereinafter in primary reference to GaN materials is applicable to the formation of various other (Al, Ga, In)N material species. Further, (Al,Ga,In)N materials within the scope of the invention may further include minor quantities of dopants and/or other impurity or inclusional materials. Boron (B) may also be included.

One approach to eliminating the spontaneous and piezoelectric polarization effects in GaN or III-nitride based optoelectronic devices is to grow the HI-nitride devices on nonpolar planes of the crystal. Such planes contain equal numbers of Ga (or group III atoms) and N atoms and are charge-neutral. Furthermore, subsequent nonpolar layers are equivalent to one another so the bulk crystal will not be polarized along the growth direction. Two such families of symmetry-equivalent nonpolar planes in GaN are the {11-20} family, known collectively as a-planes, and the {1-100} family, known collectively as m-planes. Thus, nonpolar III-nitride is grown along a direction perpendicular to the (0001) c-axis of the III-nitride crystal.

Another approach to reducing polarization effects in (Ga,Al,In,B)N devices is to grow the devices on semi-polar planes of the crystal. The term “semi-polar plane” (also referred to as “semipolar plane”) can be used to refer to any plane that cannot be classified as c-plane, a-plane, or m-plane. In crystallographic terms, a semi-polar plane may include any plane that has at least two nonzero h, i, or k Miller indices and a nonzero l Miller index.

Some commonly observed examples of semi-polar planes include the (11-22), (10-11), and (10-13) planes. Other examples of semi-polar planes in the wurtzite crystal structure include, but are not limited to, (10-12), (20-21), and (10-14). The nitride crystal's polarization vector lies neither within such planes or normal to such planes, but rather lies at some angle inclined relative to the plane's surface normal. For example, the (10-11) and (10-13) planes are at 62.98° and 32.06° to the c-plane, respectively.

The Gallium or Ga face of GaN is the c⁺ or (0001) plane, and the Nitrogen or N-face of GaN or a III-nitride layer is the c⁻ or (000-1) plane.

The prefix n- (e.g., n-GaN) represents n-type and the prefix p- (e.g., p-GaN) represents p-type.

A Group III-V or III-V material is a material comprising an alloy of at least one element from Group III of the periodic table and at least one element from Group V of the periodic table.

### REFERENCES

The following references are incorporated by reference herein:

1. Lund et al., J. Appl. Phys, 123, 055702 (2018).

### CONCLUSION

This concludes the description of the preferred embodiment of the present invention. The foregoing description of one or more embodiments of the invention has been presented for the purposes of illustration and description. It is not intended to be exhaustive or to limit the invention to the precise form disclosed. Many modifications and variations are possible in light of the above teaching. It is intended that the scope of the invention be limited not by this detailed description, but rather by the claims appended hereto.

1. A method of making a device, comprising:
(a) forming one or more at least partially relaxed features comprising one or more planar layers, one or more nanostructures, and/or one or more microstructures, on a first substrate; and
(b) bonding a second substrate to the at least partially relaxed features on the first substrate.

2. The method of claim 1, wherein the at least partially relaxed features are rigid or hard.

3. The method of claim 2, wherein at least some of the at least partially relaxed features crack under stress, but serve to preserve others of the features from cracking.

4. The method of claim 1, wherein the features are plastic or soft.

5. The method of claim 4, wherein the features deform under stress to increase a bonding area.

6. The method of claim 1, wherein the features comprise InGaN quantum dots (QDs).

7. The method of claim 6, wherein the InGaN quantum dots are grown on n-GaN on the first substrate and are bonded to p-GaN on the second substrate.

8. The method of claim 1, wherein the features comprise a significant lattice mismatch with the second substrate, the significant mismatch corresponding to the lattice mismatch arising from the features having a different crystal orientation or different material than the second part.

9. The method of claim 1, wherein the features are not planar.

10. The method of claim 1, comprising repeating the steps (a) and (b) so as to form a device comprising a plurality of pairs comprising the first substrate bonded to the second substrate, wherein the second substrate in a first one of the pairs is the first substrate in the next pair formed on top of the first one of the pairs.

11. The method of claim 1, wherein at least one of the first substrate or the second substrate are undergoing, or in a stage of, processing.

12. The method of claim 1, further comprising forming a layer comprising an active region on the first substrate, the active region including the at least partially relaxed features on the first substrate.

13. A device, comprising:
at least partially relaxed features formed on a first substrate; and
a second substrate bonded to the at least partially relaxed features.

14. The device of claim 13, wherein the at least partially relaxed features are rigid or hard.

15. The device of claim 14, wherein some of the at least partially relaxed features crack under stress, but serve to preserve others of the at least partially relaxed features from cracking.

16. The device of claim 15, wherein the at least partially relaxed features are plastic or soft.

17. The device of claim 16, wherein the at least partially relaxed features deform under stress to increase a bonding area.

18. The device of claim 13, further comprising a layer comprising an active region on the first substrate, the active region including the at least partially relaxed features and the at least partially relaxed features comprising quantum dots.

19. The device of claim 18, wherein the quantum dots (QDs) comprise InGaN QDs and the first substrate and the second substrate comprise gallium nitride.

20. The device of claim 13, wherein the at least partially relaxed features are not planar or a first surface of the first substrate in contact with the at least partially relaxed features is not parallel to a second surface of the second substrate in contact with the features.

21.-33. (canceled)
